(19) United States
(12) Patent Application Publication
(10) Pub. No.: US 2024/0359445 A1
(43) Pub. Date: Oct. 31, 2024

(54) MULTILAYER SUBSTRATE

(71) Applicant: Murata Manufacturing Co., Ltd., Nagaokakyo-shi (JP)

(72) Inventors: Kosuke NISHIO, Nagaokakyo-shi (JP); Takayuki SHIMAMURA, Nagaokakyo-shi (JP); Sunao FUKUTAKE, Nagaokakyo-shi (JP)

(21) Appl. No.: 18/766,841

(22) Filed: Jul. 9, 2024

Related U.S. Application Data
(63) Continuation of application No. PCT/JP2023/010391, filed on Mar. 16, 2023.

(30) Foreign Application Priority Data
Apr. 14, 2022 (JP) 2022-066670

(51) Int. Cl. B32B 27/36; B32B 3/26; B32B 7/05; B32B 7/08; B32B 27/08; B32B 33/00; G02F 1/00; G02F 1/1333; G02F 1/1345

(52) U.S. Cl. CPC B32B 27/36; B32B 3/266; B32B 7/05; B32B 7/08; B32B 27/08; B32B 33/00; G02F 1/0045; G02F 1/133365; G02F 1/13452; B32B 2305/55; B32B 2307/202; B32B 2307/704; B32B 2307/724; B32B 2367/00

(57) ABSTRACT

A multilayer body includes liquid crystal polymer layers including first, second, and third liquid crystal polymer layers stacked on each other in a Z-axis direction. The first liquid crystal polymer layer is located farther toward a positive side of the Z axis than the rest of the plural liquid crystal polymer layers. The third liquid crystal polymer layer is located farther toward a negative side of the Z axis than the rest of the plural liquid crystal polymer layers. At least one first conductive layer is located between the first liquid crystal polymer layer and the second liquid crystal polymer layer and/or between the second liquid crystal polymer layer and the third liquid crystal polymer layer. A gas permeability amount of the first liquid crystal polymer layer per unit volume and that of the third liquid crystal polymer layer are greater than that of the second liquid crystal polymer layer.

### CROSS REFERENCE TO RELATED APPLICATIONS

This application claims the benefit of priority to Japanese Patent Application No. 2022-066670 filed on Apr. 14, 2022 and is a Continuation Application of PCT Application No. PCT/JP2023/010391 filed on Mar. 16, 2023. The entire contents of each application are hereby incorporated herein by reference.

### BACKGROUND OF THE INVENTION

### 1. Field of the Invention

The present invention relates to multilayer substrates each including multiple liquid crystal polymer layers stacked on each other.

### 2. Description of the Related Art

As an invention of a multilayer substrate of the related art, a resin multilayer substrate disclosed in International Publication No. 2019/098012, for example, is known. This resin multilayer substrate includes plural insulating resin base materials and plural conductive patterns. The plural insulating resin base layers are stacked on each other in the up-down direction. The plural conductive patterns are disposed within the resin multilayer substrate. Gas vent holes are provided in the plural conductive patterns. With this configuration, a gas generated inside the resin multilayer substrate during the manufacturing thereof can be ejected to the outside of the resin multilayer substrate via the gas vent holes.

### SUMMARY OF THE INVENTION

In the field of the resin multilayer substrate disclosed in International Publication No. 2019/098012, it is desirable to eject a gas generated inside the resin multilayer substrate to the outside thereof and also to reduce the entry of air containing moisture into the inside of the resin multilayer substrate.

Example embodiments of the present invention provide multilayer substrates each able to eject a gas generated inside the multilayer substrate to the outside thereof and also to reduce the entry of air containing moisture into the inside of the multilayer substrate.

A multilayer substrate according to example embodiment of the present invention includes a multilayer body and at least one conductive layer. The multilayer body includes liquid crystal polymer layers including first, second, and third liquid crystal polymer layers stacked on each other in a Z-axis direction. The first liquid crystal polymer layer is located farther toward a positive side of the Z axis than remaining liquid crystal polymer layers of the plural liquid crystal polymer layers. The third liquid crystal polymer layer is located farther toward a negative side of the Z axis than remaining liquid crystal polymer layers of the plural liquid crystal polymer layers. The second liquid crystal polymer layer is located between the first liquid crystal polymer layer and the third liquid crystal polymer layer in the Z-axis direction. The at least one conductive layer is in the multilayer body. The at least one conductive layer includes at least one first conductive layer located between the first liquid crystal polymer layer and the second liquid crystal polymer layer and/or between the second liquid crystal polymer layer and the third liquid crystal polymer layer. A gas permeability amount of the first liquid crystal polymer layer per unit volume and a gas permeability amount of the third liquid crystal polymer layer per unit volume are greater than a gas permeability amount of the second liquid crystal polymer layer per unit volume.

A multilayer substrate according to an example embodiment of the present invention includes a multilayer body and at least one conductive layer. The multilayer body includes plural liquid crystal polymer layers including first, second, and third liquid crystal polymer layers stacked on each other in a Z-axis direction. The first liquid crystal polymer layer is located farther toward a positive side of the Z axis than remaining liquid crystal polymer layers of the plural liquid crystal polymer layers. The third liquid crystal polymer layer is located farther toward a negative side of the Z axis than remaining liquid crystal polymer layers of the plural liquid crystal polymer layers. The second liquid crystal polymer layer is located between the first liquid crystal polymer layer and the third liquid crystal polymer layer in the Z-axis direction. The at least one conductive layer is in the multilayer body. The at least one conductive layer includes at least one first conductive layer located between the first liquid crystal polymer layer and the second liquid crystal polymer layer and/or between the second liquid crystal polymer layer and the third liquid crystal polymer layer. The crystallinity of the second liquid crystal polymer layer is higher than the crystallinity of the first liquid crystal polymer layer and the crystallinity of the third liquid crystal polymer layer.

Using a multilayer substrate according to an example embodiment of the present invention makes it possible to eject a gas generated inside the multilayer substrate to the outside thereof and also to reduce the entry of air containing moisture into the inside of the multilayer substrate.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is an exploded perspective view of a multilayer substrate 10.

FIG. 2 is a sectional view of the multilayer substrate 10.

FIG. 3 is a front view of the multilayer substrate 10 when it is used.

FIG. 4 is an exploded perspective view of a multilayer substrate 10a.

FIG. 5 is a top view of liquid crystal polymer layers 16a, 17, and 16c of a multilayer substrate 10b.

FIG. 6 is a sectional view of a multilayer substrate 10c.

FIG. 7 is a front view of the multilayer substrate 10c when it is used.

FIG. 8 is a sectional view of a multilayer substrate 10d.

FIG. 9 is a sectional view of a multilayer substrate 10e.

### DETAILED DESCRIPTION OF THE EXAMPLE EMBODIMENTS

### Example Embodiments

### Structure of Multilayer Substrate

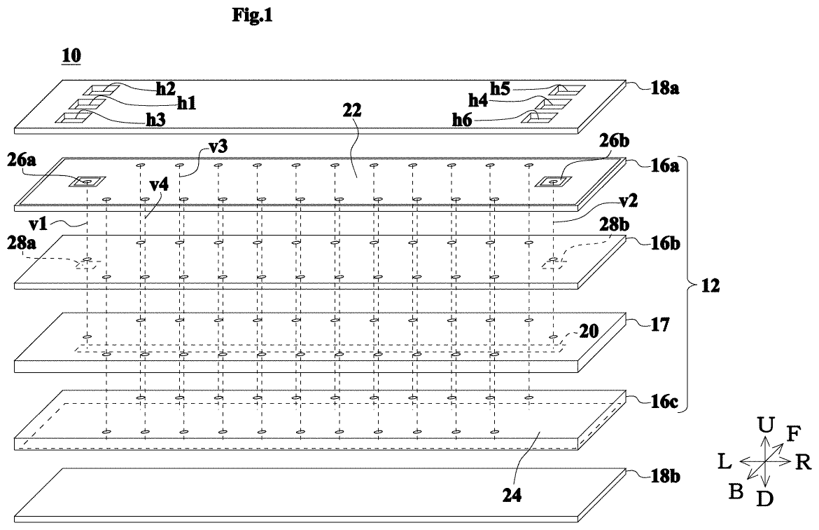

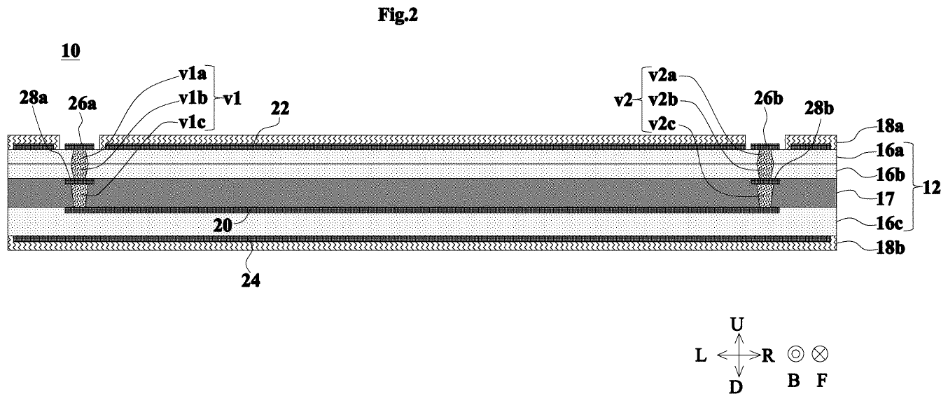

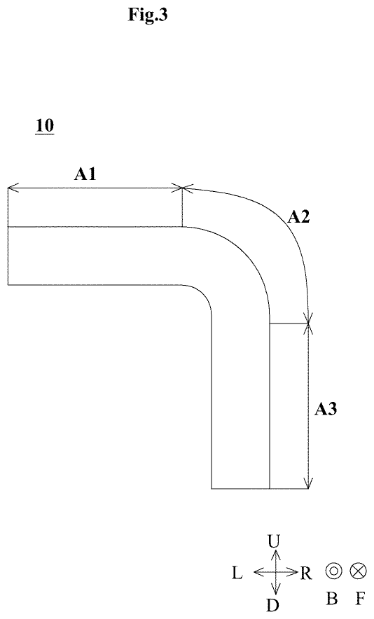

The structure of a multilayer substrate 10 according to an example embodiment of the present invention will be described below with reference to the drawings. FIG. 1 is an exploded perspective view of the multilayer substrate 10. FIG. 2 is a sectional view of the multilayer substrate 10. In FIG. 2, a cross section perpendicular to the front-back direction is shown. FIG. 3 is a front view of the multilayer substrate 10 when it is used. In FIG. 1, among multiple interlayer connecting conductors v3 and v4, only representative interlayer connecting conductors v3 and v4 are designated by reference signs.

In the specification, directions are defined as follows. The stacking direction of layers of a multilayer body 12 of the multilayer substrate 10 is defined as an up-down direction. The up-down direction coincides with the Z-axis direction. The up direction is toward the positive side of the Z axis. The down direction is toward the negative side of the Z axis. The extending direction of a signal conductive layer 20 of the multilayer substrate 10 is defined as a left-right direction. The widthwise direction of the signal conductive layer 20 as seen in the up-down direction is defined as a front-back direction. The up-down direction, the front-back direction, and the left-right direction are perpendicular to each other. The up direction and the down direction of the up-down direction may be replaced by each other. The left direction and the right direction of the left-right direction may be replaced by each other. The front direction and the back direction of the front-back direction may be replaced by each other.

In the following description, X is a component or a member of the multilayer substrate 10. In the specification, the individual portions of X are defined as follows and are used as such unless otherwise stated. A front portion of X means a front half of X. A back portion of X means a back half of X. A left portion of X means a left half of X. A right portion of X means a right half of X. A top portion of X means a top half of X. A bottom portion of X means a bottom half of X. A front end of X means the end of X in the front direction. A back end of X means the end of X in the back direction. A left end of X means the end of X in the left direction. A right end of X means the end of X in the right direction. A top end of X means the end of X in the up direction. A bottom end of X means the end of X in the down direction. A front end portion of X means the front end of X and the vicinity thereof. A back end portion of X means the back end of X and the vicinity thereof. A left end portion of X means the left end of X and the vicinity thereof. A right end portion of X means the right end of X and the vicinity thereof. A top end portion of X means the top end of X and the vicinity thereof. A bottom end portion of X means the bottom end of X and the vicinity thereof.

The structure of the multilayer substrate 10 will first be explained below with reference to FIG. 1. A radio-frequency signal is transmitted through the multilayer substrate 10. The multilayer substrate 10 is used in an electronic device, such as a smartphone, to electrically connect two circuits. As illustrated in FIG. 1, the multilayer substrate 10 includes a multilayer body 12, protection layers 18a and 18b, signal conductive layer 20 (at least one conductive layer), a first ground conductive layer 22 (at least one conductive layer), a second ground conductive layer 24 (at least one conductive layer), signal terminals 26a and 26b (at least one conductive layer), connecting conductive layers 28a and 28b (at least one conductive layer), interlayer connecting conductors v1 and v2, and plural interlayer connecting conductors v3 and v4.

The multilayer body 12 has a planar shape. The multilayer body 12 thus has a top main surface and a bottom main surface. The top main surface and the bottom main surface of the multilayer body 12 each have a rectangular or substantially rectangular shape having long sides extending in the left-right direction. Accordingly, the length of the multilayer body 12 in the left-right direction is longer than that of the multilayer body 12 in the front-back direction. The multilayer body 12 has flexibility.

As illustrated in FIG. 1, the multilayer body 12 has a structure in which liquid crystal polymer layers 16a through 16c and 17 including a liquid crystal polymer layer 16a (first liquid crystal polymer layer), a liquid crystal polymer layer 17 (second liquid crystal polymer layer), and a liquid crystal polymer layer 16c (third liquid crystal polymer layer) are stacked on each other in the Z-axis direction. The liquid crystal polymer layers 16a, 16b, 17, and 16c are arranged in the downward direction in this order. The liquid crystal polymer layer 16a (first liquid crystal polymer layer) is located at the topmost position (toward the positive side of the Z axis) among the liquid crystal polymer layers 16a through 16c and 17. The liquid crystal polymer layer 16c (third liquid crystal polymer layer) is located at the bottommost position (toward the negative side of the Z axis) among the liquid crystal polymer layers 16a through 16c and 17. The liquid crystal polymer layer 17 (second liquid crystal polymer layer) is disposed between the liquid crystal polymer layer 16a (first liquid crystal polymer layer) and the liquid crystal polymer layer 16c (third liquid crystal polymer layer) in the up-down direction (Z-axis direction). Each of the liquid crystal polymer layers 16a through 16c and the liquid crystal polymer layer 17 (second liquid crystal polymer layer) includes a top main surface (positive main surface located on the positive side of the Z axis) and a bottom main surface (negative main surface located on the negative side of the Z axis).

No insulating layer, which is made of a material different from the liquid crystal polymer layers, is interposed between the liquid crystal polymer layers 16a and 16b, between the liquid crystal polymer layers 16b and 17, and between the liquid crystal polymer layers 17 and 16c. The liquid crystal polymer layer 16a thus contacts the liquid crystal polymer layer 16b. The liquid crystal polymer layer 16a is fusion-bonded to the liquid crystal polymer layer 16b. The liquid crystal polymer layer 16b contacts the liquid crystal polymer layer 17. The liquid crystal polymer layer 16b is fusion-bonded to the liquid crystal polymer layer 17. The liquid crystal polymer layer 17 contacts the liquid crystal polymer layer 16c. The liquid crystal polymer layer 17 is fusion-bonded to the liquid crystal polymer layer 16c.

The gas permeability amount of each of the liquid crystal polymer layer 16a (first liquid crystal polymer layer), the liquid crystal polymer layer 16b, and the liquid crystal polymer layer 16c (third liquid crystal polymer layer) per unit volume is greater than that of the liquid crystal polymer layer 17 (second liquid crystal polymer layer). The gas permeability amount is the oxygen permeability amount at 25° C. (the environment in which the multilayer substrate 10 is used) and the carbon dioxide permeability amount at 200° C. (when the multilayer body is pressure-bonded). The gas permeability amount is measured in the following manner, for example. A liquid crystal polymer layer having a predetermined area and a predetermined thickness is first prepared. A gas is sealed in a space facing the top main surface of the liquid crystal polymer layer, while a space facing the bottom main surface of the liquid crystal polymer layer is set in a vacuum state. Then, after the lapse of a preset time, the amount of gas accumulated in the space facing the bottom main surface of the liquid crystal polymer layer is measured. The gas is water vapor.

To implement the above-described structure, the crystallinity of the liquid crystal polymer layer 17 (second liquid crystal polymer layer) is set to be higher than that of each of the liquid crystal polymer layer 16a (first liquid crystal polymer layer), the liquid crystal polymer layer 16b, and the liquid crystal polymer layer 16c (third liquid crystal polymer layer). The crystallinity of the liquid crystal polymer layers is measured by x-ray diffraction, DSC (differential scanning calorimetry), FT-IR, or solid-state NMR, for example. As DSC, DSC3 made by Mettler-Toledo International Inc., for example, can be used. The crystallinity and the gas permeability amount have a correlation. More specifically, as the crystallinity becomes higher, the gas permeability amount becomes smaller.

The modulus of elasticity of each of the liquid crystal polymer layer 16a (first liquid crystal polymer layer), the liquid crystal polymer layer 16b, and the liquid crystal polymer layer 16c (third liquid crystal polymer layer) is lower than that of the liquid crystal polymer layer 17 (second liquid crystal polymer layer).

To implement the above-described structure, as the material of the liquid crystal polymer layer 16a (first liquid crystal polymer layer), the liquid crystal polymer layer 16b, and the liquid crystal polymer layer 16c (third liquid crystal polymer layer), a wholly aromatic polyester resin having lower than 50 mol % of 2-hydroxy-6-naphthoic acid, for example, is used. As the material of the liquid crystal polymer layer 17 (second liquid crystal polymer layer), a wholly aromatic polyester resin having 50 mol % or higher of 2-hydroxy-6-naphthoic acid, for example, is used.

With the use of the above-described materials, the dissipation factor of the liquid crystal polymer layer 17 (second liquid crystal polymer layer) becomes smaller than that of each of the liquid crystal polymer layer 16a (first liquid crystal polymer layer), the liquid crystal polymer layer 16b, and the liquid crystal polymer layer 16c (third liquid crystal polymer layer).

A radio-frequency signal is transmitted through the signal conductive layer 20. The signal conductive layer 20 (first conductive layer) is disposed between the liquid crystal polymer layer 17 (second liquid crystal polymer layer) and the liquid crystal polymer layer 16C (third liquid crystal polymer layer). In the present example embodiment, the signal conductive layer 20 (first conductive layer, sixth conductive layer) is located on the bottom main surface (negative main surface) of the liquid crystal polymer layer 17 (second liquid crystal polymer layer). The signal conductive layer 20 (first conductive layer, inner conductive layer) thus contacts the liquid crystal polymer layer 17 (second liquid crystal polymer layer). The signal conductive layer 20 has a linear shape extending in the left-right direction.

As shown in FIG. 1, the first ground conductive layer 22 is provided in the multilayer body 12. The first ground conductive layer 22 is located above the signal conductive layer 20 (on the positive side of the Z axis) and also overlaps the signal conductive layer 20 as seen in the up-down direction (Z-axis direction). In the present example embodiment, the first ground conductive layer 22 is disposed on the top main surface of the liquid crystal polymer layer 16a (first liquid crystal polymer layer). The first ground conductive layer 22 (third conductive layer) thus contacts the liquid crystal polymer layer 16a (first liquid crystal polymer layer). The first ground conductive layer 22 also covers the substantially entirety of the top main surface of the liquid crystal polymer layer 16a. Accordingly, the area of the first ground conductive layer 22 (third conductive layer) is larger than that of the signal conductive layer 20 (inner conductive layer). A ground potential is connected to the first ground conductive layer 22.

As shown in FIG. 1, the second ground conductive layer 24 is provided in the multilayer body 12. The second ground conductive layer 24 is located below the signal conductive layer 20 (on the negative side of the Z axis) and also overlaps the signal conductive layer 20 as seen in the up-down direction (Z-axis direction). In the present example embodiment, the second ground conductive layer 24 is disposed on the bottom main surface of the liquid crystal polymer layer 16c (third liquid crystal polymer layer). The second ground conductive layer 24 (fourth conductive layer) thus contacts the liquid crystal polymer layer 16c (third liquid crystal polymer layer). The second ground conductive layer 24 also covers the substantially entirety of the bottom main surface of the liquid crystal polymer layer 16c. Accordingly, the area of the second ground conductive layer 24 (fourth conductive layer) is larger than that of the signal conductive layer 20 (inner conductive layer). A ground potential is connected to the second ground conductive layer 24. The signal conductive layer 20 and the first and second ground conductive layers 22 and 24 configured as described above have a stripline structure.

The signal terminal 26a is disposed on the left end portion of the multilayer body 12. The signal terminal 26a will be explained more specifically. The signal terminal 26a is located on the top main surface of the liquid crystal polymer layer 16a. The signal terminal 26a overlaps the left end portion of the signal conductive layer 20 as seen in the up-down direction. The signal terminal 26a has a rectangular or substantially rectangular shape as seen in the up-down direction. The signal terminal 26a is an external terminal into and from which a radio-frequency signal is input and output. The signal terminal 26a does not contact the first ground conductive layer 22.

The connecting conductive layer 28a is provided at the left end portion of the multilayer body 12. The connecting conductive layer 28a will be explained more specifically. The connecting conductive layer 28a (first conductive layer) is disposed between the liquid crystal polymer layer 16a (first liquid crystal polymer layer) and the liquid crystal polymer layer 17 (second liquid crystal polymer layer). In the present example embodiment, the connecting conductive layer 28a is located on the bottom main surface of the liquid crystal polymer layer 16b. In other words, the connecting conductive layer 28a (first conductive layer, fifth conductive layer) is located on the top main surface (positive main surface) of the liquid crystal polymer layer 17 (second liquid crystal polymer layer). The connecting conductive layer 28a overlaps the left end portion of the signal conductive layer 20 as seen in the up-down direction. The connecting conductive layer 28a has a rectangular or substantially rectangular shape as seen in the up-down direction.

The interlayer connecting conductor v1 electrically connects the signal terminal 26a, the connecting conductive layer 28a, and the left end portion of the signal conductive layer 20. More specifically, as illustrated in FIG. 2, the interlayer connecting conductor v1 includes interlayer connecting conductors v1a, v1b, and v1c. The interlayer connecting conductor v1a passes through the liquid crystal polymer layer 16a in the up-down direction. The interlayer connecting conductor v1a contacts the signal terminal 26a, but does not pass through the signal terminal 26a in the up-down direction. The interlayer connecting conductor v1b passes through the liquid crystal polymer layer 16b in the up-down direction. The interlayer connecting conductor v1b contacts the interlayer connecting conductor v1a and the connecting conductive layer 28a, but does not pass through the connecting conductive layer 28a in the up-down direction. The interlayer connecting conductor v1c passes through the liquid crystal polymer layer 17 (second liquid crystal polymer layer) in the up-down direction. The interlayer connecting conductor v1c contacts the connecting conductive layer 28a (fifth conductive layer) and the signal conductive layer 20 (sixth conductive layer). However, the interlayer connecting conductor v1c does not pass through the connecting conductive layer 28a (fifth conductive layer) and the signal conductive layer 20 (sixth conductive layer) in the up-down direction (Z-axis direction). The structures of the signal terminal 26b, connecting conductive layer 28b, and interlayer connecting conductor v2 are respectively symmetrical to those of the signal terminal 26a, connecting conductive layer 28a, and interlayer connecting conductor v1 in the left-right direction, and an explanation thereof will thus be omitted.

As illustrated in FIG. 1, plural interlayer connecting conductors v3 are positioned farther frontward than the signal conductive layer 20. The plural interlayer connecting conductors v3 are aligned in the left-right direction. The plural interlayer connecting conductors v3 pass through the liquid crystal polymer layers 16a, 16b, 17, and 16c in the up-down direction. With this configuration, the plural interlayer connecting conductors v3 electrically connect the first ground conductive layer 22 and the second ground conductive layer 24 to each other.

Plural interlayer connecting conductors v4 are positioned farther backward than the signal conductive layer 20. The plural interlayer connecting conductors v4 are aligned in the left-right direction. The plural interlayer connecting conductors v4 pass through the liquid crystal polymer layers 16a, 16b, 17, and 16c in the up-down direction. With this configuration, the plural interlayer connecting conductors v4 electrically connect the first ground conductive layer 22 and the second ground conductive layer 24 to each other.

The above-described first and second ground conductive layers 22 and 24, signal terminals 26a and 26b, and connecting conductive layers 28a and 28b are formed by, for example, etching on a metal foil provided on the top main surface or the bottom main surface of each of the liquid crystal polymer layers 16a through 16c and 17. The metal foil is a copper foil, for example.

The interlayer connecting conductors v1 through v4 are via-hole conductors, for example. The via-hole conductors are formed by making through-holes in the liquid crystal polymer layers 16a through 16c and 17, filling a conductive paste into the through-holes, and sintering the conductive paste. The material of the interlayer connecting conductors v1 through v4 is a mixture of a resin and a metal, however, it may include only a metal without a resin.

The protection layer 18a (first protection layer) covers the top main surface (main surface on the positive side of the z axis) of the multilayer body 12 so as to protect the first ground conductive layer 22. Cavities h1 through h6 are formed in the protection layer 18a. The cavity h1 overlaps the signal terminal 26a as viewed in the up-down direction. The signal terminal 26a is thus exposed to the outside of the multilayer substrate 10. The cavity h2 is positioned at the front side of the cavity h1. Part of the first ground conductive layer 22 is exposed to the outside of the multilayer substrate 10 via the cavity h2. The cavity h3 is positioned at the back side of the cavity h1. Part of the first ground conductive layer 22 is exposed to the outside of the multilayer substrate 10 via the cavity h3. With this configuration, certain portions of the first ground conductive layer 22 serve as ground terminals. The structure of the cavities h4 through h6 is symmetrical to that of the cavities h1 through h3 in the left-right direction and an explanation thereof will thus be omitted.

The protection layer 18b (second protection layer) covers the bottom main surface (main surface on the negative side of the Z axis) of the multilayer body 12 so as to protect the second ground conductive layer 24.

The above-described protection layers 18a and 18b do not contain a liquid crystal polymer and are not part of the multilayer body 12. The protection layers 18a and 18b are resist layers, for example. The gas permeability amount of the protection layer 18a (first protection layer) per unit volume and that of the protection layer 18b (second protection layer) are greater than that of the liquid crystal polymer layer 16a (first liquid crystal polymer layer) and that of the liquid crystal polymer layer 16c (third liquid crystal polymer layer). The protection layers 18a and 18b are formed after a step of thermally pressure-bonding the multilayer body 12.

The multilayer substrate 10 configured as described above has flexibility. The multilayer substrate 10 can thus bend, as shown in FIG. 3. More specifically, the multilayer substrate 10 has a first section A1, a second section A2, and a third section A3. In a state in which the multilayer substrate 10 is not bent, the first section A1, second section A2, and third section A3 are arranged in this order from the left to the right. The second section A2 is bent downward from the first section A1. The first section A1 and the third section A3 are not bent. The first section A1 and the third section A3 may be bent slightly, in which case, the radius of curvature of the first section A1 and that of the third section A3 are larger than that of the second section A2.

### Advantages

Using the multilayer substrate 10 makes it possible to eject a gas generated inside the multilayer substrate 10 to the outside thereof and also to reduce the entry of air containing moisture into the inside of the multilayer substrate 10. More specifically, in the multilayer substrate 10, the gas permeability amount of each of the liquid crystal polymer layer 16a (first liquid crystal polymer layer) and the liquid crystal polymer layer 16c (third liquid crystal polymer layer) per unit volume is larger than that of the liquid crystal polymer layer 17 (second liquid crystal polymer layer). With this configuration, a gas generated within the multilayer substrate 10 during the manufacturing thereof is ejected to the outside of the multilayer substrate 10 via the liquid crystal polymer layers 16a and 16c. When the multilayer substrate 10 is used, air containing moisture is less likely to enter the inside of the multilayer substrate 10 because of the presence of the liquid crustal polymer layer 17. Moisture in the liquid crystal polymer layer 17 can thus be reduced.

The bottom main surfaces of the connecting conductive layers 28a and 28b (first conductive layer) disposed between the liquid crystal polymer layer 16a (first liquid crystal polymer layer) and the liquid crystal polymer layer 17 (second liquid crystal polymer layer) are located near the liquid crystal polymer layer 17. In the present example embodiment, the bottom main surfaces of the connecting conductive layers 28a and 28b (first conductive layer) contact the liquid crystal polymer layer 17. With this configuration, a decrease in moisture in the liquid crystal polymer layer 17 can regulate the occurrence of the erosion of the bottom main surfaces of the connecting conductive layers 28a and 28b (first conductive layer) and the vicinities thereof caused by moisture. Likewise, the top main surface of the signal conductive layer 20 (first conductive layer) disposed between the liquid crystal polymer layer 17 (second liquid crystal polymer layer) and the liquid crystal polymer layer 16c (third liquid crystal polymer layer) is located near the liquid crystal polymer layer 17. In the present example embodiment, the top main surface of the signal conductive layer 20 (first conductive layer) contacts the liquid crystal polymer layer 17. With this configuration, a decrease in moisture in the liquid crystal polymer layer 17 can regulate the occurrence of the erosion of the top main surface of the signal conductive layer 20 and the vicinity thereof caused by moisture.

As illustrated in FIG. 3, when the multilayer substrate 10 is bent, a high tensile stress is applied to the liquid crystal polymer layer 16a and a high compressive stress is applied to the liquid crystal polymer layer 16c, while neither of a compressive stress nor a tensile stress is likely to be applied to the liquid crystal polymer layer 17. To address this issue, the crystallinity of the liquid crystal polymer layer 16a (first liquid crystal polymer layer) and that of the liquid crystal polymer layer 16c (third liquid crystal polymer layer) are lower than that of the liquid crystal polymer layer 17 (second liquid crystal polymer layer). The modulus of elasticity of each of the liquid crystal polymer layers 16a and 16c thus becomes lower than that of the liquid crystal polymer layer 17. Hence, the liquid crystal polymer layers 16a and 16c can be more easily deformed so as to be less likely to be broken.

With the application of heat, the liquid crystal polymer layers 16a through 16c and 17 easily undergo plastic deformation. When the liquid crystal polymer layers 16a through 16c and 17 are heated, a gas is likely to be generated therein. It is more convenient if the modulus of elasticity of the liquid crystal polymer layers 16a and 16c, which are located near the surfaces of the multilayer body 12, is low when the multilayer substrate 10 is bent. In the multilayer substrate 10, therefore, the crystallinity of the liquid crystal polymer layers 16a and 16c is low. With the above-described configuration, a gas generated in the multilayer body 12 can be ejected to the outside thereof, and also, the multilayer body 12 can be bent more easily.

The material of the liquid crystal polymer layer 16a (first liquid crystal polymer layer), the liquid crystal polymer layer 16b, and the liquid crystal polymer layer 16c (third liquid crystal polymer layer) is a wholly aromatic polyester resin having lower than 50 mol % of 2-hydroxy-6-naphthoic acid, for example. The material of the liquid crystal polymer layer 17 (second liquid crystal polymer layer) is a wholly aromatic polyester resin having 50 mol % or higher of 2-hydroxy-6-naphthoic acid, for example. With the use of these materials, the gas permeability amount of the liquid crystal polymer layer 16a (first liquid crystal polymer layer) per unit volume and that of the liquid crystal polymer layer 16c (third liquid crystal polymer layer) become larger than that of the liquid crystal polymer layer 17 (second liquid crystal polymer layer). As a result, the use of the multilayer substrate 10 makes it possible to eject a gas generated within the multilayer substrate 10 to the outside thereof and also to reduce the entry of air containing moisture into the inside of the multilayer substrate 10.

The signal conductive layer 20 contacts the liquid crystal polymer layer 17 (second liquid crystal polymer layer). With the use of the above-described materials, the dissipation factor of the liquid crystal polymer layer 17 (second liquid crystal polymer layer) becomes smaller than that of each of the liquid crystal polymer layer 16a (first liquid crystal polymer layer) and the liquid crystal polymer layer 16c (third liquid crystal polymer layer). This can lower a dielectric loss of a radio-frequency signal transmitted through the signal conductive layer 20.

The use of the multilayer substrate 10 can eject a gas generated within the multilayer substrate 10 to the outside thereof and also reduce the entry of air containing moisture into the inside of the multilayer substrate 10. This will be explained more specifically. The multilayer body 12 is formed by stacking the liquid crystal polymer layers 16a through 16c and 17 on each other and then by heat-pressing the liquid crystal polymer layers 16a through 16c and 17. During the heat pressing, a gas is generated in the multilayer body 12. The signal conductive layer 20 (inner conductive layer) having a small area contacts the liquid crystal polymer layer 17 (second liquid crystal polymer layer) having a smaller gas permeability amount. The first ground conductive layer 22 (third conductive layer) having a large area contacts the liquid crystal polymer layer 16a (first liquid crystal polymer layer) having a larger gas permeability amount. The second ground conductive layer 24 (fourth conductive layer) having a large area contacts the liquid crystal polymer layer 16c (third liquid crystal polymer layer) having a larger gas permeability amount. With this configuration, the gas generated in the liquid crystal polymer layer 17 is likely to be ejected to the outside of the multilayer substrate 10 since the liquid crystal polymer layer 17 is not considerably covered by the signal conductive layer 20. In the multilayer substrate 10, therefore, the signal conductive layer 20 and the connecting conductive layers 28a and 28b are not easily come off. Additionally, air containing moisture is less likely to enter the inside of the multilayer substrate 10 since the liquid crystal polymer layer 16a is considerably covered by the first ground conductive layer 22 and the liquid crystal polymer layer 16c is considerably covered by the second ground conductive layer 24.

The gas permeability amount of the protection layer 18a (first protection layer) and that of the protection layer 18b (second protection layer) per unit volume are greater than that of the liquid crystal polymer layer 16a (first liquid crystal polymer layer) and that of the liquid crystal polymer layer 16c (third liquid crystal polymer layer). This can further promote the ejection of a gas generated within the multilayer substrate 10 to the outside thereof and further reduce the entry of air containing moisture into the inside of the multilayer substrate 10.

In the multilayer substrate 10, the material of the interlayer connecting conductor v1c is a mixture of a resin and a metal. Such an interlayer connecting conductor v1c is hardened by heat during the manufacturing of the multilayer substrate 10, and at this time, a gas is generated from the interlayer connecting conductor v1c. The interlayer connecting conductor v1c does not pass through the connecting conductive layer 28a (fifth conductive layer) and the signal conductive layer 20 (sixth conductive layer) in the up-down direction (Z-axis direction). The gas is thus likely to be trapped between the connecting conductive layer 28a (fifth conductive layer) and the signal conductive layer 20 (sixth conductive layer).

In the multilayer substrate 10, the gas permeability amount of the liquid crystal polymer layer 16a (first liquid crystal polymer layer) per unit volume and that of the liquid crystal polymer layer 16c (third liquid crystal polymer layer) are greater than that of the liquid crystal polymer layer 17 (second liquid crystal polymer layer). With this configuration, a gas generated within the multilayer substrate 10 during the manufacturing thereof is ejected to the outside of the multilayer substrate 10 via the liquid crystal polymer layers 16a and 16c. When the multilayer substrate 10 is used, air containing moisture is less likely to enter the inside of the multilayer substrate 10 because of the liquid crystal polymer layer 17, thereby reducing the moisture in the liquid crystal polymer layer 17.

### First Modified Example

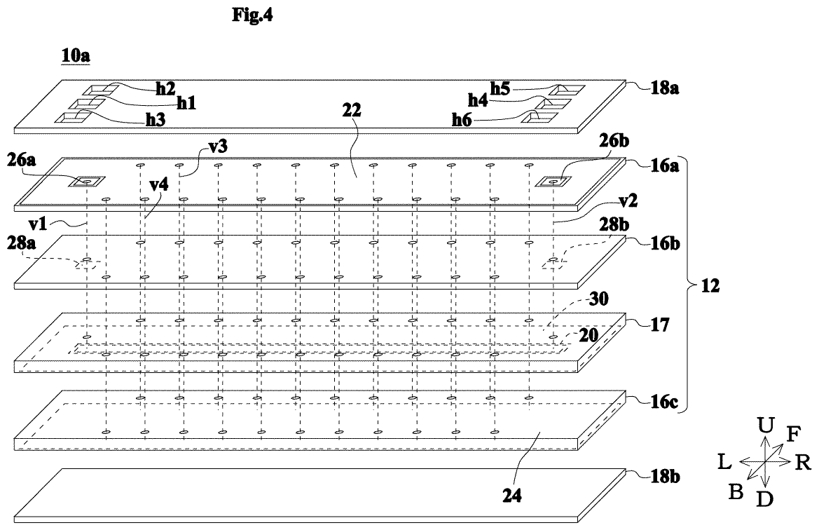

A multilayer substrate 10a according to a first modified example embodiment will be described below with reference to the drawing. FIG. 4 is an exploded perspective view of the multilayer substrate 10a.

The multilayer substrate 10a is different from the multilayer substrate 10 in that it also includes a third ground conductive layer 30. The third ground conductive layer 30 is disposed on the bottom main surface of the liquid crystal polymer layer 17. The third ground conductive layer 30 covers the most part of the liquid crystal polymer layer 17, but it is insulated from the signal conductive layer 20. The third ground conductive layer 30 surrounds the signal conductive layer 20 therearound, as viewed in the up-down direction. The third ground conductive layer 30 is electrically connected to the first and second ground conductive layers 22 and 24 via the interlayer connecting conductors v3 and v4 and is thus connected to a ground potential. The structure of the other elements of the multilayer substrate 10a is the same as that of the multilayer substrate 10 and an explanation thereof will be omitted. The multilayer substrate 10a can obtain the same advantages as those of the multilayer substrate 10.

### Second Modified Example

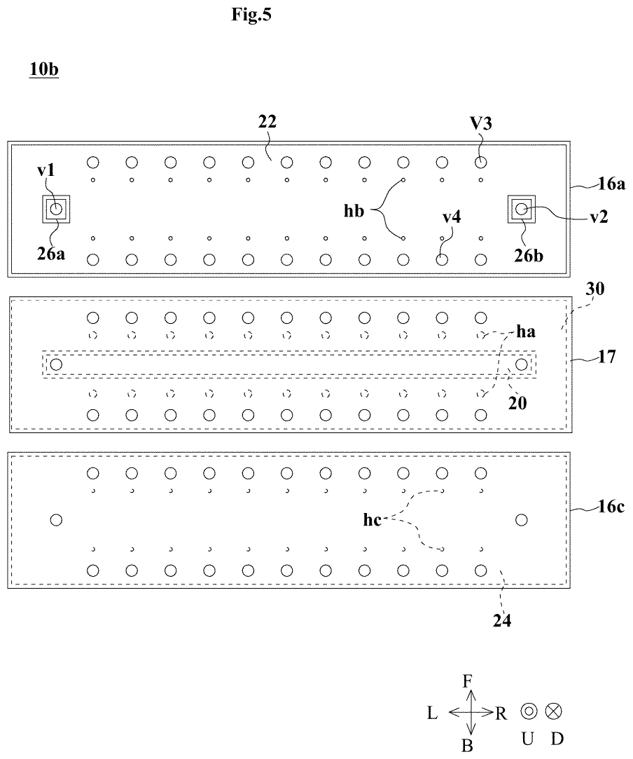

A multilayer substrate 10b according to a second modified example embodiment will be described below with reference to the drawing. FIG. 5 is a top view of liquid crystal polymer layers 16a, 17, and 16c of the multilayer substrate 10b.

The multilayer substrate 10b is different from the multilayer substrate 10a in that it has plural holes ha through hc. This will be explained more specifically. The third ground conductive layer 30 (second conductive layer) contacts the liquid crystal polymer layer 17 (second liquid crystal polymer layer). The plural holes ha (first holes) are provided in the third ground conductive layer 30 (second conductive layer) to pass through the third ground conductive layer 30 (second conductive layer) in the up-down direction (Z-axis direction). At least some of the plural holes ha (first holes) have the same size and are arranged at equal spacings. In the present example embodiment, the plural holes ha are arranged in two lines in the left-right direction. The area of the holes ha (first holes) seen in the up-down direction (Z-axis direction) is smaller than that of the interlayer connecting conductors v1 through v4 seen in the up-down direction (Z-axis direction). The area of the interlayer connecting conductors v1 through v4 seen in the up-down direction is the area of regions surrounded by the outer edges of the interlayer connecting conductors v1 through v4 when they are seen through in the up-down direction. The holes ha are provided only in the third ground conductive layer 30 and are not provided in the liquid crystal polymer layer 17. For example, the holes ha are not through-holes which pass through the liquid crystal polymer layer 17 in the up-down direction and which are provided with a metal on the inner peripheral surface of the through-holes.

The first ground conductive layer 22 (third conductive layer) contacts the liquid crystal polymer layer 16a (first liquid crystal polymer layer). The plural holes hb (second holes) are provided in the first ground conductive layer 22 (third conductive layer) to pass through the first ground conductive layer 22 (third conductive layer) in the up-down direction (Z-axis direction). At least some of the plural holes hb (second holes) have the same size and are arranged at equal spacings. In the example embodiment, the plural holes hb are arranged in two lines in the left-right direction. The area of the holes hb (second holes) seen in the up-down direction (Z-axis direction) is smaller than that of the holes ha (first holes) seen in the up-down direction (Z-axis direction).

The second ground conductive layer 24 (fourth conductive layer) contacts the liquid crystal polymer layer 16c (third liquid crystal polymer layer). The plural holes hc (third holes) are provided in the second ground conductive layer 24 (fourth conductive layer) to pass through the second ground conductive layer 24 (fourth conductive layer) in the up-down direction (Z-axis direction). At least some of the plural holes hc (third holes) have the same size and are arranged at equal spacings. In the present example embodiment, the plural holes hc are arranged in two lines in the left-right direction. The area of the holes hc (third holes) seen in the up-down direction (Z-axis direction) is smaller than that of the holes ha (first holes) seen in the up-down direction (Z-axis direction). The structure of the other elements of the multilayer substrate 10b is the same as that of the multilayer substrate 10a and an explanation thereof will be omitted. The multilayer substrate 10b can obtain the same advantages as those of the multilayer substrate 10a.

As discussed above, the area of the holes hb (second holes) seen in the up-down direction (Z-axis direction) or that of the holes hc (third holes) seen in the up-down direction (Z-axis direction) is smaller than that of the holes ha (first holes) seen in the up-down direction (Z-axis direction). This can reduce a leakage of noise via the liquid crystal polymer layer 16a.

The smaller area of the holes hb provided in the first ground conductive layer 22 and the smaller area of the holes hc provided in the second ground conductive layer 24 can reduce or prevent the radiation of noise from the multilayer substrate 10b and also reduce the entry of noise into the multilayer substrate 10b. Additionally, the potential of the first and second ground conductive layers 22 and 24 can be stabilized at a ground potential.

### Third Modified Example

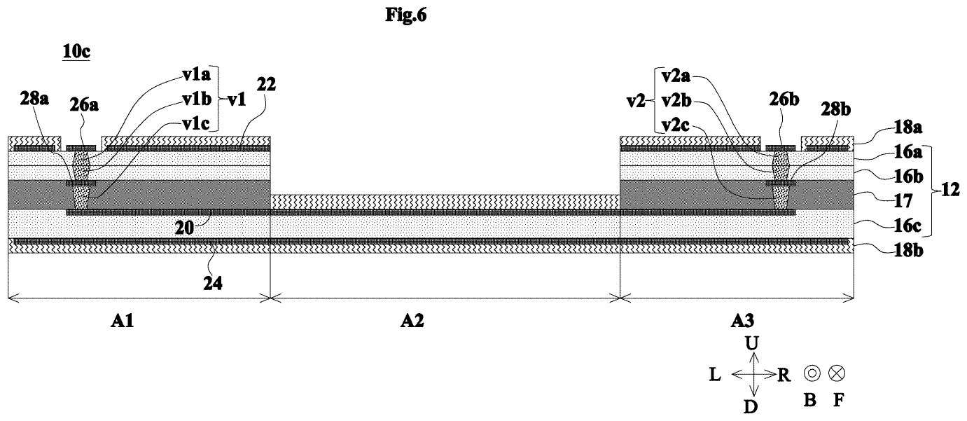

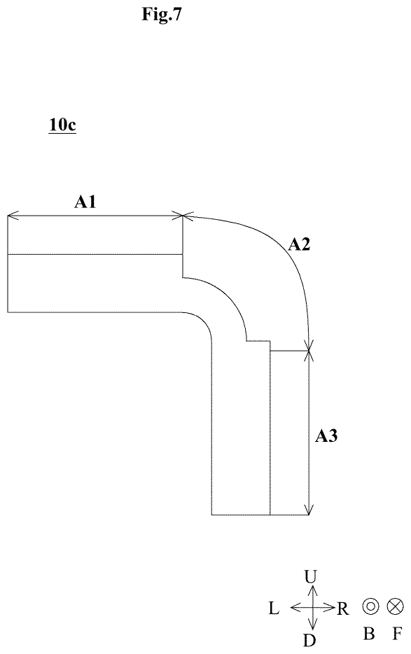

A multilayer substrate 10c according to a third modified example embodiment will be described below with reference to the drawings. FIG. 6 is a sectional view of the multilayer substrate 10c. FIG. 7 is a front view of the multilayer substrate 10c when it is used.

The multilayer substrate 10c is different from the multilayer substrate 10 in that the thickness of the second section A2 in the up-down direction is smaller than that of the first section A1 and the third section A3 in the up-down direction. The second section A2 does not have the liquid crystal polymer layers 16a, 16b, and 17. With this configuration, the second section A2 can be deformed more easily than the first section A1 and the third section A3. That is, the second section A2 serves as a flexible region, while the first section A1 and the third section A3 serve as rigid regions. As shown in FIG. 7, the second section A2 is bent downward from the first section A1. The structure of the other elements of the multilayer substrate 10c is the same as that of the multilayer substrate 10 and an explanation thereof will be omitted. The multilayer substrate 10c can obtain the same advantages as those of the multilayer substrate 10.

In the multilayer substrate 10c, the second section A2 does not include the liquid crystal polymer layer 17 having a high modulus of elasticity. This makes the second section A2 bend even more easily. The modulus of elasticity is the modulus of elasticity at room temperature. The room temperature is about 5° C. to about 35° C., for example.

### Fourth Modified Example

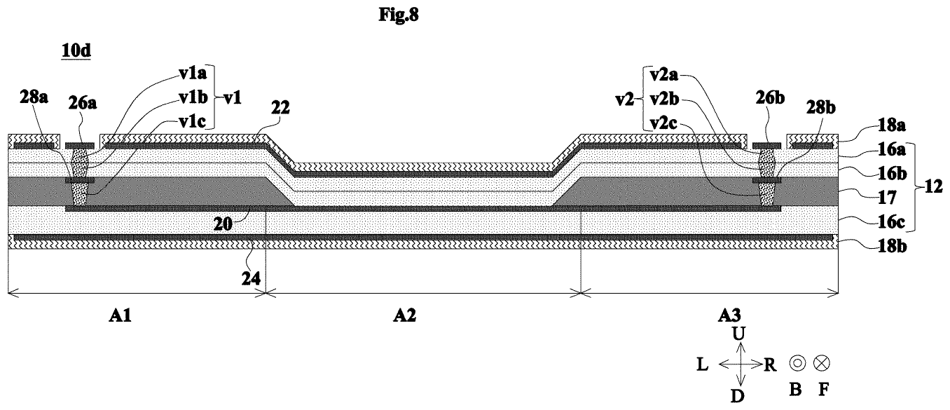

A multilayer substrate 10d according to a fourth modified example embodiment will be described below with reference to the drawing. FIG. 8 is a sectional view of the multilayer substrate 10d.

The multilayer substrate 10d is different from the multilayer substrate 10 in that the second section A2 does not have the liquid crystal polymer layer 17. In this manner, the second section A2 does not include the liquid crystal polymer layer 17 having a high modulus of elasticity. This makes the second section A2 bend even more easily. The structure of the other elements of the multilayer substrate 10d is the same as that of the multilayer substrate 10 and an explanation thereof will be omitted. The multilayer substrate 10d can obtain the same advantages as those of the multilayer substrate 10.

### Fifth Modified Example

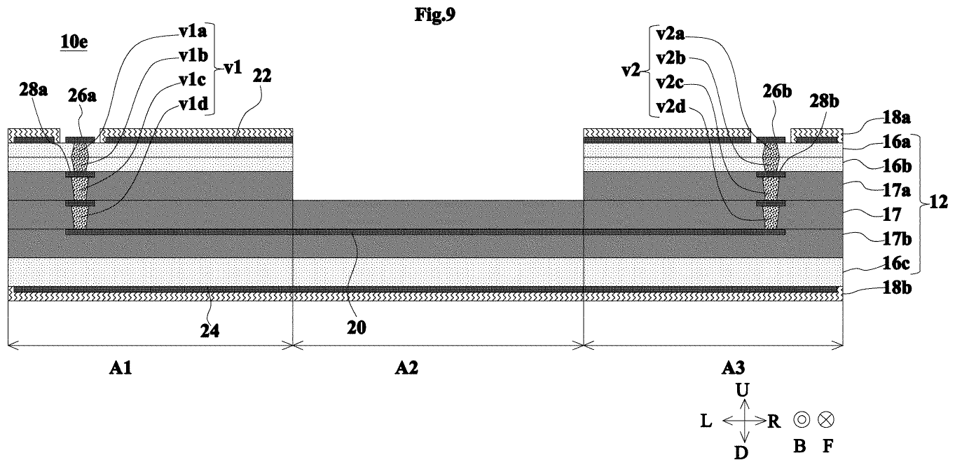

A multilayer substrate 10e according to a fifth modified example embodiment will be described below with reference to the drawing. FIG. 9 is a sectional view of the multilayer substrate 10e.

The multilayer substrate 10e is different from the multilayer substrate 10c in that the multilayer body 12 also includes liquid crystal polymer layers 17a and 17b. More specifically, the liquid crystal polymer layer 17a is stacked above the liquid crystal polymer layer 17, while the liquid crystal polymer layer 17b is stacked under the liquid crystal polymer layer 17. In this manner, multiple liquid crystal polymer layers having a small gas permeability amount may be provided. With this configuration, the signal conductive layer 20 is sandwiched between the liquid crystal polymer layers 17 and 17b having a small gas permeability amount in the up-down direction. This can make it less likely to erode the signal conductive layer 20. The structure of the other elements of the multilayer substrate 10e is the same as that of the multilayer substrate 10c and an explanation thereof will be omitted. The multilayer substrate 10e can obtain the same advantages as those of the multilayer substrate 10.

### OTHER EXAMPLE EMBODIMENTS

The multilayer substrates according to example embodiments of the present invention are not limited to the multilayer substrates 10 and 10a through 10e and may be modified within the scope and spirit of the present invention. The structures of the multilayer substrates 10 and 10a through 10e may be combined in a desired manner.

The protection layers 18a and 18b are not essential elements. Only one of the protection layers 18a and 18b may be provided.

The first and second ground conductive layers 22 and 24 are not essential elements. Only one of the first and second ground conductive layers 22 and 24 may be provided.

The liquid crystal polymer layers 16a through 16c and 17 may be made of the same material. In this case, the liquid crystal polymer layers 16a through 16c and 17 are made of a porous material, for example, and the porosity of the liquid crystal polymer layer 17 is lower than that of the liquid crystal polymer layers 16a through 16c. Then, the gas permeability amount of the liquid crystal polymer layers 16a through 16c per unit volume becomes larger than that of the liquid crystal polymer layer 17. As a result, a gas within the multilayer body 12 is ejected to the outside thereof.

The first conductive layer may be disposed only one of between the liquid crystal polymer layer 16a (first liquid crystal polymer layer) and the liquid crystal polymer layer 17 (second liquid crystal polymer layer) and between the liquid crystal polymer layer 17 (second liquid crystal polymer layer) and the liquid crystal polymer layer 16c (third liquid crystal polymer layer).

The type of interlayer connecting conductors v1 through v4 may be other than via-hole conductors. For example, the interlayer connecting conductors v1 through v4 may be through-hole conductors. The through-hole conductors are formed by plating the inner peripheral surfaces of through-holes which pass through the liquid crystal polymer layers in the up-down direction.

The protection layers 18a and 18b are provided in order to prevent conductive layers from being exposed and to protect them from erosion. From this point of view, it is not essential that the gas permeability amount of the protection layers 18a and 18b per unit volume is greater than that of the liquid crystal polymer layers 16a and 16c. The gas permeability amount of the protection layers 18a and 18b per unit volume may be smaller than or equal to that of the liquid crystal polymer layers 16a and 16c.

The interlayer connecting conductor v1c may pass through the connecting conductive layer 28a (fifth conductive layer) and the signal conductive layer 20 (sixth conductive layer) in the up-down direction (Z-axis direction).

In the multilayer substrate 10e, a liquid crystal polymer layer may be provided between the liquid crystal polymer layers 17a and 17 and/or between the liquid crystal polymer layers 17 and 17b. This liquid crystal polymer layer has a larger gas permeability amount per unit volume than the liquid crystal polymer layers 17, 17a, and 17b.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate comprising:
a multilayer body including a plurality of liquid crystal polymer layers including first, second, and third liquid crystal polymer layers are stacked on each other in a Z-axis direction, the first liquid crystal polymer layer being located farther toward a positive side of the Z axis than remaining liquid crystal polymer layers of the plurality of liquid crystal polymer layers, the third liquid crystal polymer layer being located farther toward a negative side of the Z axis than remaining liquid crystal polymer layers of the plurality of liquid crystal polymer layers, the second liquid crystal polymer layer being located between the first liquid crystal polymer layer and the third liquid crystal polymer layer in the Z-axis direction; and
at least one conductive layer in the multilayer body; wherein
the at least one conductive layer includes at least one first conductive layer located between the first liquid crystal polymer layer and the second liquid crystal polymer layer and/or between the second liquid crystal polymer layer and the third liquid crystal polymer layer; and
a gas permeability amount of the first liquid crystal polymer layer per unit volume and a gas permeability amount of the third liquid crystal polymer layer per unit volume are greater than a gas permeability amount of the second liquid crystal polymer layer per unit volume.

2. The multilayer substrate according to claim 1, wherein a modulus of elasticity of the first liquid crystal polymer layer and a modulus of elasticity of the third liquid crystal polymer layer are lower than a modulus of elasticity of the second liquid crystal polymer layer.

3. The multilayer substrate according to claim 1, wherein
a material of the first liquid crystal polymer layer and a material of the third liquid crystal polymer layer are a wholly aromatic polyester resin having lower than 50 mol % of 2-hydroxy-6-naphthoic acid; and
a material of the second liquid crystal polymer layer is a wholly aromatic polyester resin having 50 mol % or higher of 2-hydroxy-6-naphthoic acid.

4. The multilayer substrate according to claim 1, wherein
the at least one first conductive layer includes a signal conductive layer to transmit a radio-frequency signal transmitting therethrough;
the signal conductive layer contacts the second liquid crystal polymer layer;
the multilayer substrate further comprising at least one of:
a first ground conductive layer that is located farther toward the positive side of the Z axis than the signal conductive layer and that overlaps the signal conductive layer as seen in the Z axis; or
a second ground conductive layer that is located farther toward the negative side of the Z axis than the signal conductive layer and that overlaps the signal conductive layer as seen in the Z axis; wherein
a dissipation factor of the second liquid crystal polymer layer is smaller than a dissipation factor of the first liquid crystal polymer layer and a dissipation factor of the third liquid crystal polymer layer.

5. The multilayer substrate according to claim 1, wherein
the at least one conductive layer includes a second conductive layer; and
a plurality of first holes are provided in the second conductive layer extending through the second conductive layer in the Z-axis direction.

6. The multilayer substrate according to claim 5, wherein at least some of the plurality of first holes have an identical size and are arranged at equal spacings.

7. The multilayer substrate according to claim 5, further comprising:
an interlayer connecting conductor extending through the liquid crystal polymer layers in an up-down direction.

8. The multilayer substrate according to claim 7, wherein an area of the first holes seen in the Z-axis direction is smaller than an area of the interlayer connecting conductor seen in the Z-axis direction.

9. The multilayer substrate according to claim 5, further comprising at least one of:
a third conductive layer that contacts the first liquid crystal polymer layer; or
a fourth conductive layer that contacts the third liquid crystal polymer layer; wherein
at least one of: a plurality of second holes are provided in the third conductive layer extending through the third conductive layer in the Z-axis direction, or a plurality of third holes are provided in the fourth conductive layer extending through the fourth conductive layer in the Z-axis direction.

10. The multilayer substrate according to claim 1, wherein
the at least one first conductive layer includes an inner conductive layer that contacts the second liquid crystal polymer layer;
the multilayer substrate further comprising at least one of:
a third conductive layer that contacts the first liquid crystal polymer layer; or
a fourth conductive layer that contacts the third liquid crystal polymer layer; wherein
an area of the third conductive layer and an area of the fourth conductive layer are larger than an area of the inner conductive layer.

11. The multilayer substrate according to claim 1, further comprising at least one of:
a first protection layer that covers a main surface of the multilayer body on the positive side of the Z axis; or
a second protection layer that covers a main surface of the multilayer body on the negative side of the Z axis; wherein
the first protection layer and the second protection layer do not include a liquid crystal polymer.

12. The multilayer substrate according to claim 11, wherein a gas permeability amount of the first protection layer per unit volume and a gas permeability amount of the second protection layer per unit volume are greater than the gas permeability amount of the first liquid crystal polymer layer per unit volume and the gas permeability amount of the third liquid crystal polymer layer per unit volume.

13. The multilayer substrate according to claim 12, further comprising:
an interlayer connecting conductor extending through the second liquid crystal polymer layer in the Z-axis direction; wherein
the second liquid crystal polymer layer includes a positive main surface located on the positive side of the Z axis and a negative main surface located on the negative side of the Z axis;
the at least one first conductive layer includes fifth and sixth conductive layers, the fifth conductive layer being on the positive main surface of the second liquid crystal polymer layer, the sixth conductive layer being on the negative main surface of the second liquid crystal polymer layer; and
the interlayer connecting conductor contacts the fifth and sixth conductive layers and does not extend through the fifth and sixth conductive layers in the Z-axis direction.

14. The multilayer substrate according to claim 13, wherein a material of the interlayer connecting conductor is a mixture of a resin and a metal.

15. A multilayer substrate comprising:
a multilayer body including a plurality of liquid crystal polymer layers including first, second, and third liquid crystal polymer layers are stacked on each other in a Z-axis direction, the first liquid crystal polymer layer being located farther toward a positive side of the Z axis than remaining liquid crystal polymer layers of the plurality of liquid crystal polymer layers, the third liquid crystal polymer layer being located farther toward a negative side of the Z axis than remaining liquid crystal polymer layers of the plurality of liquid crystal polymer layers, the second liquid crystal polymer layer being located between the first liquid crystal polymer layer and the third liquid crystal polymer layer in the Z-axis direction; and
at least one conductive layer in the multilayer body; wherein
the at least one conductive layer includes at least one first conductive layer located at least one of between the first liquid crystal polymer layer and the second liquid crystal polymer layer or between the second liquid crystal polymer layer and the third liquid crystal polymer layer; and
a crystallinity of the second liquid crystal polymer layer is higher than a crystallinity of the first liquid crystal polymer layer and a crystallinity of the third liquid crystal polymer layer.

16. The multilayer substrate according to claim 15, wherein a modulus of elasticity of the first liquid crystal polymer layer and a modulus of elasticity of the third liquid crystal polymer layer are lower than a modulus of elasticity of the second liquid crystal polymer layer.

17. The multilayer substrate according to claim 15, wherein
a material of the first liquid crystal polymer layer and a material of the third liquid crystal polymer layer are a wholly aromatic polyester resin having lower than 50 mol % of 2-hydroxy-6-naphthoic acid; and
a material of the second liquid crystal polymer layer is a wholly aromatic polyester resin having 50 mol % or higher of 2-hydroxy-6-naphthoic acid.

18. The multilayer substrate according to claim 15, wherein
the at least one first conductive layer includes a signal conductive layer to transmit a radio-frequency signal transmitting therethrough;
the signal conductive layer contacts the second liquid crystal polymer layer;
the multilayer substrate further comprising at least one of:
a first ground conductive layer that is located farther toward the positive side of the Z axis than the signal conductive layer and that overlaps the signal conductive layer as seen in the Z axis; or
a second ground conductive layer that is located farther toward the negative side of the Z axis than the signal conductive layer and that overlaps the signal conductive layer as seen in the Z axis; wherein
a dissipation factor of the second liquid crystal polymer layer is smaller than a dissipation factor of the first liquid crystal polymer layer and a dissipation factor of the third liquid crystal polymer layer.

19. The multilayer substrate according to claim 15, wherein
the at least one conductive layer includes a second conductive layer; and
a plurality of first holes are provided in the second conductive layer extending through the second conductive layer in the Z-axis direction.

20. The multilayer substrate according to claim 19, wherein at least some of the plurality of first holes have an identical size and are arranged at equal spacings.
